(19) United States
(12) Patent Application Publication
(10) Pub. No.: US 2018/0097135 A1
(43) Pub. Date: Apr. 5, 2018

(54) SOLAR CELL MODULE AND SOLAR CELL IN WHICH WIRING MEMBER IS CONNECTED TO SURFACE

(71) Applicant: Panasonic Intellectual Property Management Co., Ltd, Osaka (JP)

(72) Inventors: Tasuku ISHIGURO, Osaka (JP); Yuya NAKAMURA, Osaka (JP)

(21) Appl. No.: 15/720,856

(22) Filed: Sep. 29, 2017

(30) Foreign Application Priority Data
Sep. 30, 2016 (JP) 2016-193775

(51) Int. Cl. H01L 31/05; H01L 31/0224; H01L 31/048

(52) U.S. Cl. CPC H01L 31/0504; H01L 31/048; H01L 31/022425

(57) ABSTRACT

A plurality of inter-cell wiring members electrically connect adjacent solar cells. The solar cell includes a photoelectric conversion layer and a finger electrode. The finger electrode is disposed on a surface of the photoelectric conversion layer and extends in a first direction. A plurality of inter-cell wiring members extend in a second direction intersecting the first direction and are arranged in the first direction, overlapping the finger electrode. The finger electrode may be formed to have a larger thickness at the end in the first direction than at the center in the first direction.

### CROSS-REFERENCE TO RELATED APPLICATION

This application is based upon and claims the benefit of priority from the prior Japanese Patent Application No. 2016-193775, filed on Sep. 30, 2016, the entire contents of which are incorporated herein by reference.

### BACKGROUND

### 1. Field

The disclosure relates to solar cells and, more particularly, to solar cell modules and solar cells in which a wiring member is connected on the surface.

### 2. Description

In a solar cell module, a plurality of solar cells are arranged on a plane and flush with each other. An electrode is formed on the surface of each solar cell. The electrodes of the two adjacent solar cells are electrically connected to via a wiring member. Further, the solar cell and the wiring member are encapsulated by a filler between a front surface member and a back surface member (see, e.g., patent document 1).

[patent document 1] JP2010-118076

If the fluidity of the filler of the solar cell module is increased under a high temperature, the solar cell may be moved. As a result of the movement, the portion of adhesion between the electrode of the solar cell and the wiring member receives a stress. The larger the stress, the more easily the wiring member comes off the solar cell. It should be noted that the stress grows larger toward the end of the surface of the solar cell.

### SUMMARY

In this background, a purpose of the present invention is to provide a technology capable of improving adhesion between the solar cell and the wiring member at the end of the surface of the solar cell.

The solar cell module according to an embodiment comprises: a plurality of solar cells; and a plurality of wiring members electrically connecting adjacent solar cells. Each of the plurality of solar cells includes: a photoelectric conversion layer; and a collecting electrode disposed on a surface of the photoelectric conversion layer and extending in a first direction. The plurality of wiring members extend in a second direction intersecting the first direction and are arranged in the first direction, overlapping the collecting electrode, and an area in which the collecting electrode is sandwiched between the wiring member and the surface of the photoelectric conversion layer is larger at an end in the first direction than at a center in the first direction.

Another embodiment of the present invention relates to a solar cell. The solar cell comprises: a photoelectric conversion layer; and a collecting electrode disposed on a surface of the photoelectric conversion layer and extending in a first direction. The collecting electrode extends in a second direction intersecting the first direction and is connectable to a plurality of wiring members arranged in the first direction, and the collecting electrode is formed to have a larger thickness at an end in the first direction than at a center in the first direction.

Still another embodiment of the present invention also relates to a solar cell. The solar cell comprises: a photoelectric conversion layer; and a collecting electrode disposed on a surface of the photoelectric conversion layer and extending in a first direction. The collecting electrode extends in a second direction intersecting the first direction and is connectable to a plurality of wiring members arranged in the first direction, and the collecting electrode includes an auxiliary electrode at a position at an end in the first direction where the wiring member is scheduled to be disposed.

### BRIEF DESCRIPTION OF THE DRAWINGS

The figures depict one or more implementations in accordance with the present teaching, by way of example only, not by way of limitations. In the figures, like reference numerals refer to the same or similar elements.

FIG. 1 is a plan view of features of a solar cell module according to an embodiment of the present invention as viewed from a light receiving surface side;

FIG. 2 is a plan view of the solar cell module of FIG. 1 as viewed from a back surface side;

FIGS. 3A-3B are plan views showing features of the solar cell of FIG. 1;

FIG. 4 is a cross sectional view of the solar cell module of FIG. 1 along the y axis;

FIG. 5 is a cross sectional view of the solar cell of FIG. 1 along the x axis;

FIGS. 6A-6B are plan views showing features of the solar cell of FIG. 1; and

FIGS. 7A-7B are plan views showing alternative features of the solar cell of FIG. 1.

### DETAILED DESCRIPTION

The invention will now be described by reference to the preferred embodiments. This does not intend to limit the scope of the present invention, but to exemplify the invention.

A brief description is now given before focusing on specific features of the present invention. An embodiment of the present invention relates to a solar cell module in which a plurality of solar cells are arranged. A plurality of finger electrodes extending in the first direction are arranged in the second direction on the surface of each solar cell. The firs direction and the second direction are defined to intersect each other. For example, the first direction and the second direction are orthogonal to each other. A plurality of wiring members extending in the second direction are connected to each of the finger electrodes such that the wiring members are arranged in the first direction. The features described above are encapsulated between two protective members by an encapsulant implemented by a filler.

If the solar cell module is subject to a high temperature, the fluidity of the encapsulant is increased. This may move the solar cell and warp the wiring member. In this process, the portion of adhesion between the finger electrode and the wiring member of the solar cell receives a stress in various directions. The larger the stress, the more easily the wiring member comes off the finger electrode. A stress received by the portion of adhesion between the finger electrode and the wiring member of the solar cell in the first direction results in a large displacement at the end of surface of the solar cell module due to the movement, causing an associated increase in the stress in the displaced portion. For this reason, the wiring member will easily come off the finger electrode at the end of the surface of the solar cell module.

In this embodiment, the adhesive force between the finger electrode and the wiring member is increased by enlarging the width of the finger at a portion of a large stress. The width of the finger electrode is not enlarged in the other portions. The terms “parallel” and “orthogonal” in the following description not only encompass completely parallel or orthogonal but also encompass slightly off-parallel within the margin of error. The term “substantially” means identical within the margin of error.

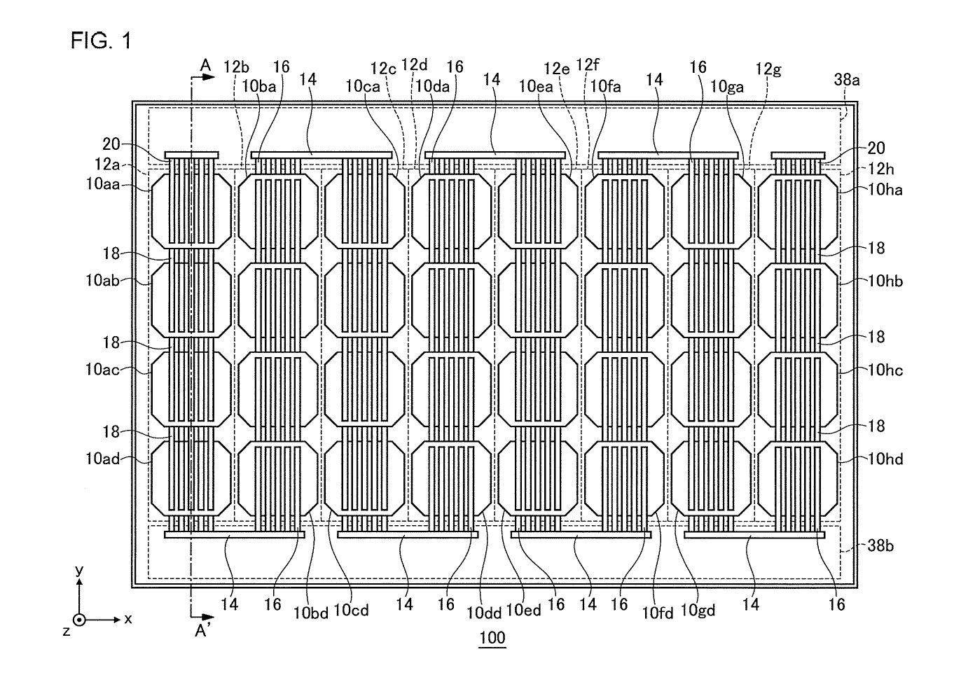

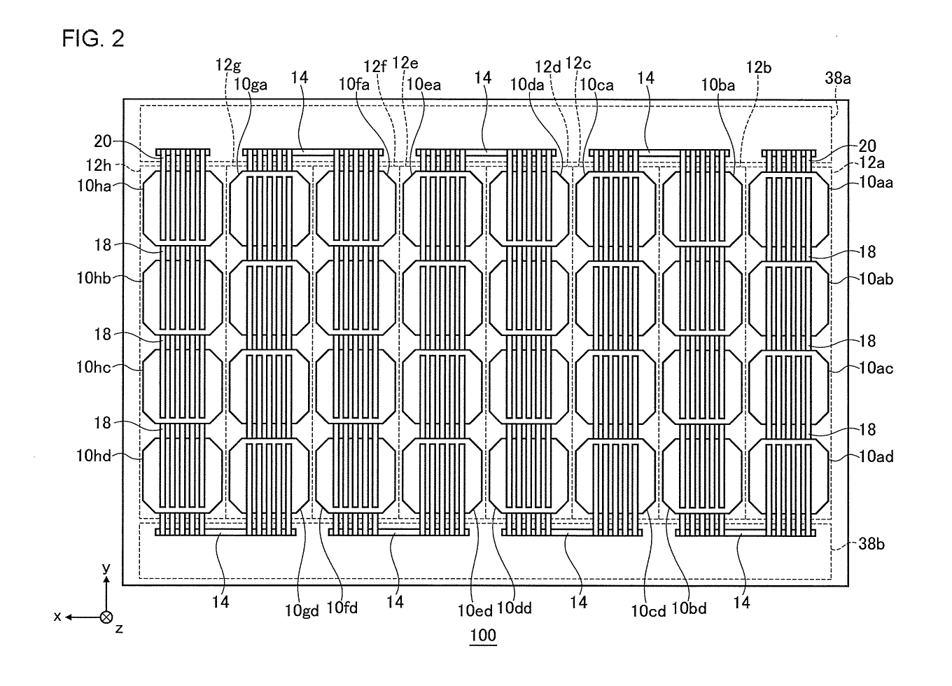

FIG. 1 is a plan view of features of a solar cell module 100 as viewed from a light receiving surface side. FIG. 2 is a plan view of the solar cell module 100 as viewed from a back surface side. As shown in FIG. 1, an orthogonal coordinate system including an x axis, y axis, and a z axis is defined. The x axis and y axis are orthogonal to each other in the plane of the solar cell module 100. The z axis is perpendicular to the x axis and y axis and extends in the direction of thickness of the solar cell module 100. The positive directions of the x axis, y axis, and z axis are defined in the directions of arrows in FIG. 1 and the negative directions are defined in the directions opposite to those of the arrows. Of the two principal surfaces forming the solar cell module 100 that are parallel to the x-y plane, the principal surface disposed on the positive direction side along the z axis is the light receiving surface, and the principal surface disposed on the negative direction side along the z axis is the back surface. Hereinafter, the positive direction side along the z axis will be referred to as “light receiving surface side” and the negative direction side along the z axis will be referred to as “back surface side”.

The solar cell module 100 includes an 11th solar cell 10aa, . . . , an 84th solar cell 10hd, which are generically referred to as solar cells 10, an inter-group wiring member 14, a group-end wiring member 16, an inter-cell wiring member 18, and a terminal wiring member 20. A first non-generating area 38a and a second non-generating area 38b are disposed to sandwich a plurality of solar cells 10 in the y axis direction. More specifically, the first non-generating area 38a is disposed farther on the positive direction side along the y axis than the plurality of solar cells 10, and the second non-generating area 38b is disposed further on the the negative direction side along the y axis than the plurality of solar cells 10. The first non-generating area 38a and the second non-generating area 38b (hereinafter, sometimes generically referred to as “non-generating areas 38”) have a rectangular shape and do not include the solar cells 10.

Each of the plurality of solar cells 10 absorbs incident light and generates photovoltaic power. The solar cell 10 is formed of, for example, a semiconductor material such as crystalline silicon, gallium arsenide (GaAs), or indium phosphorus (InP). The structure of the solar cell 10 is not limited to any particular type. In this embodiment, silicon hetero-junction solar cells are used. A stack of crystalline silicon and amorphous silicon is formed. A transparent conductive layer formed of a metal oxide (e.g., indium tin oxide) including impurities is further provided on the amorphous silicon. A collecting electrode including a highly conductive metal such as silver or copper is provided on transparent conductive layer of the solar cell 10.

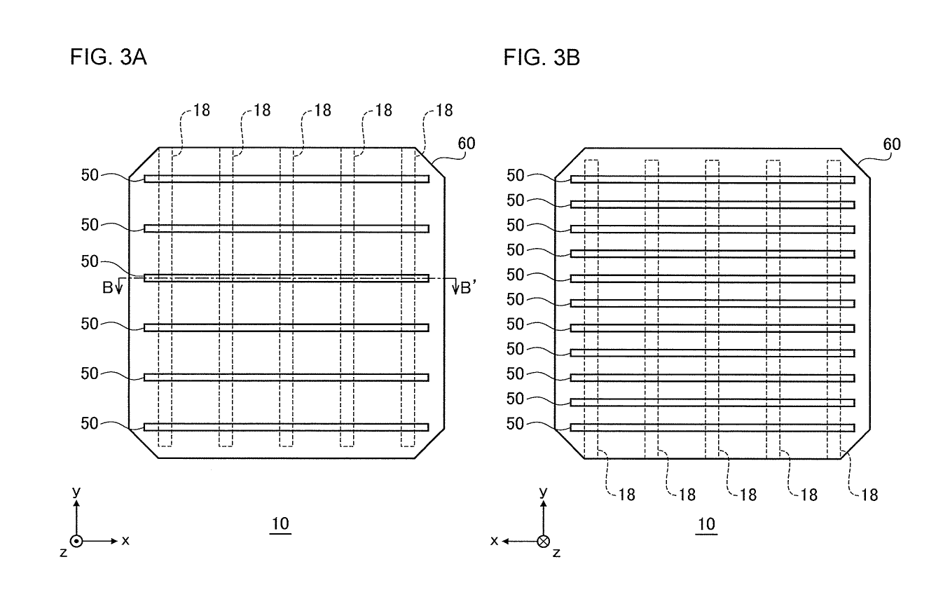

FIGS. 3A-3B are plan views showing features of the solar cell 10. FIG. 3A shows the light receiving surface of the solar cell 10 and FIG. 3B shows the back surface of the solar cell 10. Details of the features of the solar cell 10 will be described later and a summary of the features of the solar cell 10 will be given. A photoelectric conversion layer 60 corresponds to the semiconductor material mentioned above. The light receiving surface and the back surface of the photoelectric conversion layer 60 are formed in the shape of an octagon in which the longer side and the shorter side are alternately joined. The surfaces may be formed in other shapes. For example, the shorter side included in the octagon may be non-linear, or the surfaces may be shaped like a rectangle. As shown in FIG. 3A, a plurality of finger electrodes 50 extending in the x axis direction in a mutually parallel manner are disposed on the light receiving surface of the photoelectric conversion layer 60. The finger electrode 50 is formed of, for example, silver paste or the like. It is assumed here that the number of finger electrodes 50 is “6” but the number is not limited thereto.

Further, a plurality of (e.g., 5) inter-cell wiring members 18 are disposed to intersect (e.g., be orthogonal to) the plurality of finger electrodes 50 on the light receiving surface of the photoelectric conversion layer 60. The inter-cell wiring member 18 may be a material produced by coating the surface of a copper core wire with a solder. The finger electrode 50 and the inter-cell wiring member 18 are connected by a solder or adhesively attached by using a film or liquid conductive adhesive, etc. The inter-cell wiring member 18 may be simply formed of a metal such as silver, copper, or the like. The inter-cell wiring member 18 extends in the direction of adjacent solar cells 10, i.e., in the y axis direction.

As shown in FIG. 3B, the finger electrode 50 and the inter-cell wiring member 18 are disposed on the back surface of the photoelectric conversion layer 60 as in the light receiving surface of the photoelectric conversion layer 60. The number of inter-cell wiring members 18 is the same in the light receiving surface and in the back surface of the photoelectric conversion layer 60. The number of finger electrodes 50 is larger on the back surface than on the light receiving surface of the photoelectric conversion layer 60. Provided that the x axis direction corresponds to the “first direction”, the y axis direction corresponds to the “second direction”. The finger electrode 50 is also called a “collecting electrode”. A bus bar electrode may be disposed on at least one of the light receiving surface and the back surface of the solar cell 10. The bus bar electrode is disposed between the light receiving surface or the back surface of the photoelectric conversion layer 60 and the inter-cell wiring member 18 and along the inter-cell wiring member 18. Reference is made back to FIGS. 1 and 2.

The plurality of solar cells 10 are arranged in a matrix on the x-y plane. By way of example, 8 solar cells 10 are arranged in the x axis direction and 4 solar cells 10 are arranged in the y axis direction. The number of solar cells 10 arranged in the x axis direction and the number of solar cells 10 arranged in the y axis direction are not limited to the examples above. The 4 solar cells arranged and disposed in the y axis direction are connected in series by the inter-cell wiring member 18 so as to form one solar cell group 12. For example, by connecting the 11th solar cell 10aa, a 12th solar cell 10ab, a 13th solar cell 10ac, and a 14th solar cell 10ad, a 1st solar cell group 12a is formed. The other solar cell groups 12 (e.g., a 2nd solar cell group 12b through an 8th solar cell group 12h) are similarly formed. As a result, the eight solar cell groups 12 are arranged in parallel in x axis direction. The solar cell groups 12 correspond to a string.

In order to form the solar cell groups 12, the inter-cell wiring members 18 connect the finger electrode 50 on the light receiving surface side of one of adjacent solar cells 10 to the finger electrode 50 on the back surface side of the other solar cell 10. For example, the five inter-cell wiring members 18 for connecting the 11th solar cell 10aa and the 12th solar cell 10ab electrically connect the finger electrode 50 on the back surface side of the 11th solar cell 10aa and the finger electrode 50 on the light receiving surface side of the 12th solar cell 10ab. As shown in FIGS. 3A-3B, the plurality of inter-cell wiring members 18 extend in the y axis direction and are arranged in the x axis direction, overlapping the finger electrodes 50.

Three of the seven inter-group wiring members 14 are disposed in the first non-generating area 38a and the remaining four are disposed in the second non-generating area 38b. Each of the seven inter-group wiring members 14 extends in the x axis direction and is electrically connected to mutually adjacent two solar cell groups 12 via the group-end wiring members 16. For example, the 14th solar cell 10ad located on the side of the second non-generating area 38b of the 1st solar cell group 12a and a 24th solar cell 10bd located on the side of the second non-generating area 38b of the 2nd solar cell group 12b are each connected electrically to the inter-group wiring member 14 via the group-end wiring members 16. The group-end wiring members 16 are arranged similarly as the inter-cell wiring members 18 on the light receiving surface or the back surface of the solar cell 10.

The terminal wiring member 20 is connected to the 1st solar cell group 12a and the 8th solar cell group 12h located on both ends of the x axis direction. The terminal wiring member 20 connected to the 1st solar cell group 12a extends from the light receiving surface side of the 11th solar cell 10aa in the direction of the first non-generating area 38a. A pair of positive and negative lead wirings (not shown) are connected to the terminal wiring member 20.

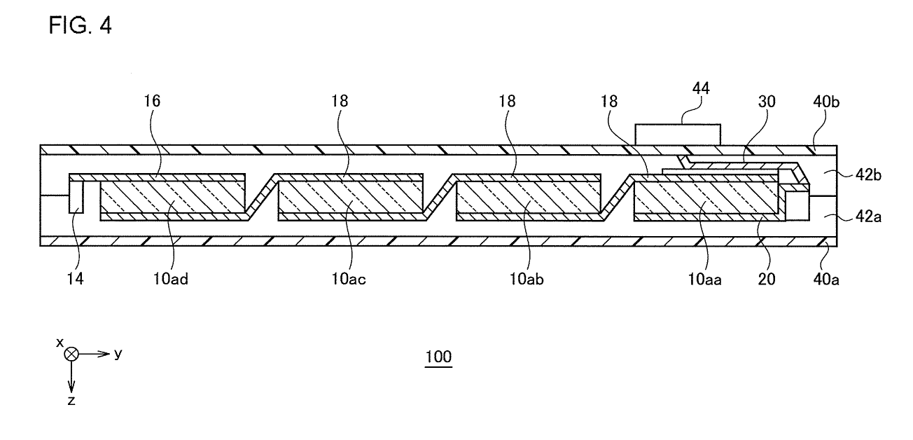

FIG. 4 is a cross sectional view of the solar cell module 100 along the y axis. The figure corresponds to the A-a cross section of FIG. 1. The solar cell module 100 includes the 11th solar cell 10aa, the 12th solar cell 10ab, the 13th solar cell 10ac, the 14th solar cell 10ad, which are generically referred to as solar cells 10, the inter-group wiring member 14, the group-end wiring member 16, the inter-cell wiring member 18, the terminal wiring member 20, a lead wiring 30, a first protective member 40a, a second protective member 40b, which are generically referred to as protective members 40, a first encapsulant 42a, a second encapsulant 42b, which are generically referred to as encapsulants 42, and a terminal box 44. The top of FIG. 4 corresponds to the back surface and the bottom corresponds to the light receiving surface.

The first protective member 40a is disposed on the light receiving surface side of the solar cell module 100 and protects the surface of the solar cell module 100. The first protective member 40a is formed by using a translucent and water shielding glass, translucent plastic, etc. and is formed in a rectangular shape. The first encapsulant 42a is stacked on the back surface of the first protective member 40a. The first encapsulant 42a is disposed between the first protective member 40a and the solar cell 10 and adhesively attaches the first protective member 40a and the solar cell 10. For example, a thermoplastic resin sheet of polyolefin, EVA, polyvinyl butyral (PVB), polyimide, or the like may be used as the first encapsulant 42a. In this embodiment a thermosetting material produced by adding a cross-linking agent to EVA is used as a material for the first encapsulant 42a. Alternatively, other types of thermoplastic resin may be used. The first encapsulant 42a has translucency and is formed of a rectangular sheet member having a surface of substantially the same dimension as the x-y plane in the first protective member 40a.

The second encapsulant 42b is stacked on the back surface of the first encapsulant 42a. The second encapsulant 42b encapsulates the plurality of solar cells 10, the inter-cell wiring members 18, etc. between the second encapsulant 42b and the first encapsulant 42a. The second encapsulant 42b may be formed of a material similar to that of the first encapsulant 42a. The second encapsulant 42b is a member disposed on the back surface of the solar cell module 100 and so should not necessarily be translucent. A light-scattering material, etc. may be included in order to reflect incident light. For example, the second encapsulant 42b may be painted in white using an inorganic oxide, etc.

Alternatively, the second encapsulant 42b may be integrated with the first encapsulant 42a by heating the members in a laminate cure process. The first encapsulant 42a and the second encapsulant 42b may contain an additive such as a wavelength changer and antioxidant as necessary. Further, the first encapsulant 42a and the second encapsulant 42b may each include a stack of a plurality of layers.

The second protective member 40b is stacked on the back surface side of the second encapsulant 42b. The second protective member 40b protects the back surface side of the solar cell module 100 as a back sheet. A resin film of, for example, polyethylene terephthalate (PET), a stack film having a structure in which an Al foil is sandwiched by resin films, or the like is used as the second protective member 40b. An opening (not shown) extending through in the z axis direction is provided in the second protective member 40b.

The terminal box 44 is formed in a cuboid shape and is adhesively attached to the second protective member 40b from the back surface side by using an adhesive like silicone so as to cover the opening (not shown) of the second protective member 40b. The lead wiring 30 is led to a bypass diode (not shown) stored in the terminal box 44. The terminal box 44 is disposed on the second protective member 40b at a position overlapping a 41st solar cell 10da and a 51st solar cell 10ea. An Al frame may be attached around the solar cell module 100.

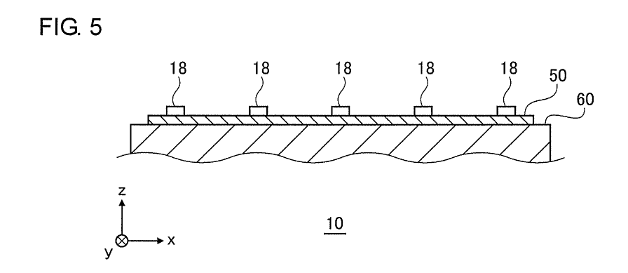

FIG. 5 is a cross sectional view of the solar cell 10 along the x axis. The figure corresponds to the B-B′ cross sectional view of FIG. 3A. The finger electrode 50 is disposed on the light receiving surface of the photoelectric conversion layer 60. The finger electrode 50 extends in the x axis direction. Five inter-cell wiring members 18 are disposed on the positive direction side of the finger electrode 50 in the z axis.

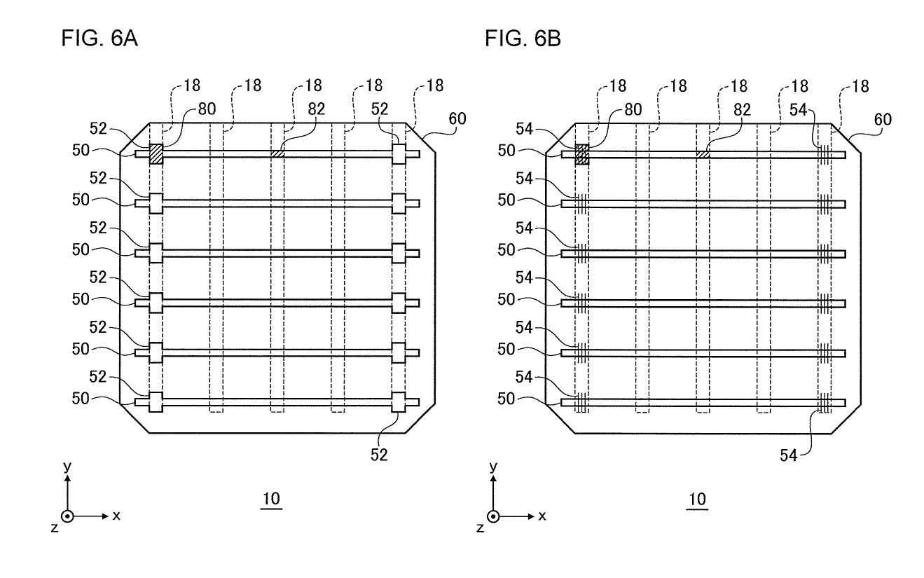

The feature of a portion of connection between the finger electrode 50 and the inter-cell wiring member 18 may be described in further detail, based on the features of the solar cell module 100 described above. FIGS. 6A-6B are plan views showing features of the solar cell 10. FIG. 6A shows the light receiving surface of the solar cell 10 and is similar to FIG. 3A. The photoelectric conversion layer 60 and the inter-cell wiring member 18 are as shown in FIG. 3A. The width in the x axis direction is common to all inter-cell wiring members 18. Meanwhile, a large-width portion 52 is formed at a portion (hereinafter, referred to as “first area 80”) of the finger electrode 50, extending in the x axis direction, connected to the inter-cell wiring member 18 at the extremity in the positive direction along the x axis and to the inter-cell wiring member at the extremity in the negative direction along the x axis. The large-width portion 52 is a portion of the finger electrode 50 where the width in the y axis direction is larger than the other portions. The length of the large-width portion 52 in the x axis direction may be identical to, shorter than, or longer than the width of the inter-cell wiring member 18 in the x axis direction.

The large-width portion 52 is provided in each of the plurality of finger electrodes 50.

Meanwhile, the width of portions (hereinafter, referred to as “second area 82”) of the finger electrode 50 connected to the other inter-cell wiring members 18 and the width of portions not connected to the inter-cell wiring members in the y axis direction is identical to the width of the finger electrode 50 of FIG. 3A. For the purpose of clarity, the figure highlights one first area 80 and one second area 82. The first area 80 and the second area 82 are defined in other portions as well. According to the feature, the area in which the large-width portion 52 and the inter-cell wiring member 18 are in contact in the first area 80 is larger than the area in which the finger electrode 50 and the inter-cell wiring member 18 are in contact in the second area 82. Therefore, the contact area in the first area 80 is larger than the contact area in the second area 82 and the adhesive force in the first area 80 is higher than the adhesive force in the second area 82. In this way, the finger electrode 50 is formed to have a larger thickness at the ends in the x axis direction than at the center in the x axis direction. The large-width portion 52 may also be formed on the back surface of the solar cell 10 similarly as shown in FIG. 6A.

FIG. 6B shows the light receiving surface of the solar cell 10 and shows an example different from that of FIG. 6A. As shown in the figure, a plurality of auxiliary electrodes 54 are disposed in the first area 80 of the finger electrode 50 extending in the x axis direction. The auxiliary electrode 54 extends in the y axis direction so as to be longer than the width of the finger electrode 50 in the y axis direction and shorter than the interval between adjacent finger electrodes 50. Further, the auxiliary electrodes 54 are arranged such that one auxiliary electrode intersects one finger electrode 50. The figure shows three auxiliary electrodes 54 disposed in one first area 80 but the number of auxiliary electrodes 54 is not limited to “3”. The auxiliary electrodes 54 are formed to be integral with the finger electrode 50 and so can be said to be included in the finger electrode 50. Further, the width of the portion in which the plurality of auxiliary electrodes 54 are arranged in the x axis direction may be identical to, smaller than, or larger than the width of the inter-cell wiring member 18 in the x axis direction. Meanwhile, the auxiliary electrode 54 is not disposed in the second area 82.

According to the feature, the area in which the inter-cell wiring member 18 is contact with the finger electrode 50 and the auxiliary electrode 54 in the first area 80 is larger than the area in which the finger electrode 50 and the inter-cell wiring member 18 are in contact in the second area 82. Therefore, the contact area in the first area 80 is larger than the contact area in the second area 82 and the adhesive force in the first area 80 is higher than the adhesive force in the second area 82. In this way, the finger electrode 50 is formed to have a larger thickness at the ends in the x axis direction than at the center in the x axis direction. The auxiliary electrodes 54 may also be formed on the back surface of the solar cell 10 similarly as shown in FIG. 6B.

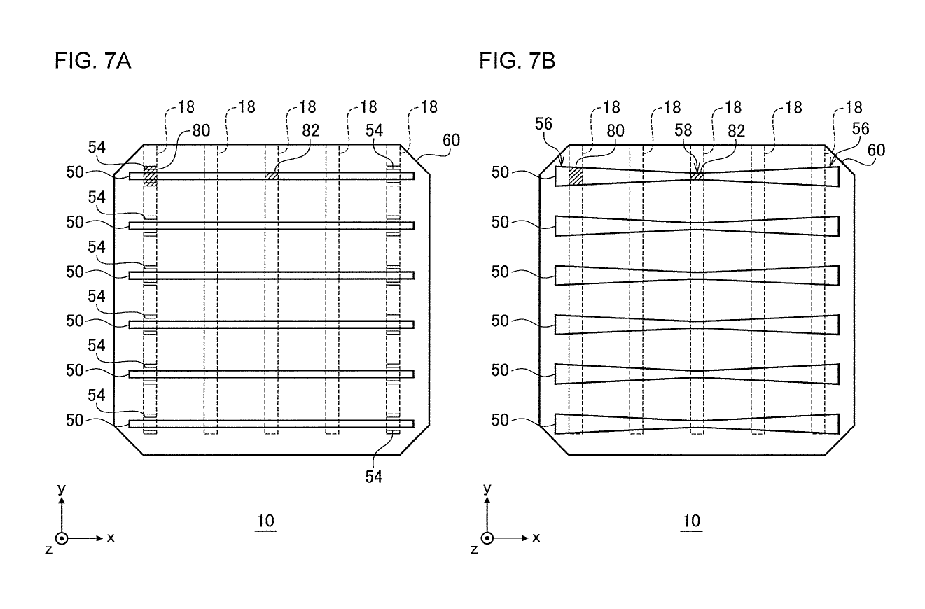

FIGS. 7A-7B are plan views showing alternative features of the solar cell 10. FIG. 7A shows the light receiving surface of the solar cell 10 and shows an example different from those described above. As shown in the figure, a plurality of auxiliary electrodes 54 are disposed in the first area 80 in the finger electrode 50 extending in the x axis direction. The auxiliary electrode 54 extends in the x axis direction in an extent substantially identical to the width of the inter-cell wiring member 18 in the x axis direction. Further, the auxiliary electrodes 54 are arranged alongside the finger electrode 50. The figure shows four auxiliary electrodes 54 disposed in one first area 80 but the number of auxiliary electrodes 54 is not limited to “4”. The auxiliary electrodes 54 are configured to be combined with the finger electrode 50 and so can be said to be included in the finger electrode 50. Further, the length of the auxiliary electrode 54 in the x axis direction may be identical to, smaller than, or larger than the width of the inter-cell wiring member 18 in the x axis direction. Meanwhile, the auxiliary electrodes 54 are not disposed in the second area 82.

According to the feature, the area in which the inter-cell wiring member 18 is contact with the finger electrode 50 and the auxiliary electrode 54 in the first area 80 is larger than the area in which the finger electrode 50 and the inter-cell wiring member 18 are in contact in the second area 82. Therefore, the contact area in the first area 80 is larger than the contact area in the second area 82 and the adhesive force in the first area 80 is higher than the adhesive force in the second area 82. In this way, the finger electrode 50 is formed to have a larger thickness at the ends in the x axis direction than at the center in the x axis direction. The auxiliary electrodes 54 may also be formed on the back surface of the solar cell 10 similarly as shown in FIG. 7A.

FIG. 7B shows the light receiving surface of the solar cell 10 and shows an example different from those described above. As shown in the figure, an end portion 56 is disposed at the positive direction end and the negative direction end of the finger electrode 50 in the x axis direction, and a central portion 58 is disposed near the center thereof in the x axis direction. The finger electrode 50 is shaped such that the width thereof in the y axis direction grows from the central portion 58 toward the end portion 56. According to the feature, the area in which the finger electrode 50 and the inter-cell wiring member 18 are in contact in the first area 80 is larger than the area in which the finger electrode 50 and the inter-cell wiring member 18 are in contact in the second area 82. Therefore, the contact area in the first area 80 is larger than the contact area in the second area 82 and the adhesive force in the first area 80 is higher than the adhesive force in the second area 82. In this way, the finger electrode 50 is formed to have a larger thickness at the end portions 56 than at the central portion 58. The finger electrode 50 of the shape of FIG. 7B may also be formed on the back surface of the solar cell 10.

A description will now be given of a method of manufacturing the solar cell module 100. First, a photoelectric conversion layer 60 is prepared. The solar cell 10 is then manufactured by forming a plurality of finger electrodes 50 extending in the x axis direction on the light receiving surface and back surface of the photoelectric conversion layer 60. In particular, the shape of the finger electrode 50 is as described above. Subsequently, a stack is formed by building the first protective member 40a, the first encapsulant 42a, the solar cell 10, the second encapsulant 42b, and the second protective member 40b in the stated order in the positive to negative direction along the z axis.

In this process, the inter-cell wiring member 18 is adhesively attached by a solder to the finger electrode 50 of the solar cell 10. A conductive film adhesive may be extracted from a roll of conductive film adhesive wound around a reel member and used to adhesively attach the finger electrode 50 and the inter-cell wiring member 18 of the solar cell 10. In this case, thermal compression is performed for adhesive attachment. Subsequently, the stack is subject to a laminate cure process. In this process, air is extracted from the stack. The stack is then heated and pressured so as to be integrated. Further, the terminal box 44 is adhesively attached to the second protective member 40b.

According to the embodiment of the present invention, the finger electrode 50 is formed to have a larger thickness at the ends in the x axis direction than at the center in the x axis direction so that the area of contact with the inter-cell wiring member 18 is ensured to be larger at the ends in the x axis direction than at the center in the x axis direction. Further, since the area of contact with the inter-cell wiring member 18 is larger at the ends in the x axis direction than at the center in the x axis direction, the contact area is ensured to be larger at the ends than at the center.

Further, since the contact area is larger at the ends than at the center, the adhesion force between the solar cell 10 and the inter-cell wiring member 18 at the ends on the surface of the solar cell 10 is increased. Further, since the adhesion force between the solar cell 10 and the inter-cell wiring member 18 at the ends on the surface of the solar cell 10 is increased, the inter-cell wiring member 18 is prevented from coming off the solar cell 10 in a high temperature. Further, since the inter-cell wiring member 18 is prevented from coming off the solar cell 10 in a high temperature, the durability of the solar cell 10 is improved. Further, since the durability of the solar cell 10 is improved, the durability of the solar cell module 100 is also improved.

Further, since the large-width portion 52 is provided in the portion of connection to the inter-cell wiring member 18 disposed at the ends in the x axis direction, a large contact area is secured between the large-width portion 52 and the inter-cell wiring member 18. Further, since the large-width portion 52 is not provided in portions other than the portion connected to the inter-cell wiring member 18 disposed at the ends in the x axis direction, reduction in the area of light receiving portion is inhibited. Further, since reduction in the area of light receiving portion is inhibited, reduction in electric power generated in the solar cell 10 is inhibited. Further, since the auxiliary electrode 54 is provided in the portion of connection to the inter-cell wiring member 18 disposed at the ends in the x axis direction, a large contact area is secured between the finger electrode 50 and the inter-cell wiring member 18. Further since the width at the end portion 56 is ensured to be larger than the width at the central portion 58, it is ensured that the closer to the end portion 56, the larger the contact area secured between the finger electrode 50 and the inter-cell wiring member 18.

A summary of the embodiment is given below. The solar cell module 100 according to the embodiment of the present invention includes a plurality of solar cells 10 and a plurality of inter-cell wiring members 18 electrically connecting adjacent solar cells 10. Each of the plurality of solar cells 10 includes a photoelectric conversion layer 60 and a finger electrode 50 disposed on the surface of the photoelectric conversion layer 60 and extending in the first direction. The plurality of inter-cell wiring members 18 extend in the second direction intersecting the first direction and are arranged in the first direction, overlapping the finger electrodes 50. The area in which the finger electrode 50 sandwiched between the inter-cell wiring member 18 and the surface of the photoelectric conversion layer 60 is larger at the ends in the first direction than at the center in the first direction.

The finger electrode 50 may be formed to have a larger thickness at the ends in the first direction than at the center in the first direction.

The finger electrode 50 may further include an auxiliary electrode 54 disposed at a position overlapping the inter-cell wiring member 18 disposed at the end in the first direction.

Another embodiment relates to the solar cell 10. The solar cell 10 includes the photoelectric conversion layer 60 and the finger electrode 50 disposed on the surface of the photoelectric conversion layer 60 and extending in the first direction. The finger electrode 50 extends in the second direction intersecting the first direction and is connectable to a plurality of inter-cell wiring members 18 arranged in the first direction. The finger electrode 50 is formed to have a larger thickness at the ends in the first direction than at the center in the first direction.

Another embodiment of the present invention also relates to the solar cell 10. The solar cell 10 includes the photoelectric conversion layer 60 and the finger electrode 50 disposed on the surface of the photoelectric conversion layer 60 and extending in the first direction. The finger electrode 50 extends in the second direction intersecting the first direction and is connectable to a plurality of inter-cell wiring members 18 arranged in the first direction. The finger electrode 50 includes an auxiliary electrode 54 at a position at the end in the first direction where the inter-cell wiring member 18 is scheduled to be disposed.

Described above is an explanation based on an exemplary embodiment. The embodiment is intended to be illustrative only and it will be obvious to those skilled in the art that various modifications to constituting elements and processes could be developed. For example, the inter-cell wiring member 18 is described as having a cross section of a rectangular strip shape. However, the cross sectional shape of the inter-cell wiring member 18 is not limited to this but may be circular, elliptical, etc.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A solar cell module comprising:
a plurality of solar cells; and
a plurality of wiring members electrically connecting adjacent solar cells, wherein
each of the plurality of solar cells includes:
a photoelectric conversion layer; and
a collecting electrode disposed on a surface of the photoelectric conversion layer and extending in a first direction,
the plurality of wiring members extend in a second direction intersecting the first direction and are arranged in the first direction, overlapping the collecting electrode, and
an area in which the collecting electrode is sandwiched between the wiring member and the surface of the photoelectric conversion layer is larger at an end in the first direction than at a center in the first direction.

2. The solar cell module according to claim 1, wherein
the collecting electrode is be formed to have a larger thickness at the end in the first direction than at the center in the first direction.

3. The solar cell module according to claim 1, wherein
the collecting electrode further includes an auxiliary electrode disposed at a position overlapping the wiring member disposed at the end in the first direction.

4. A solar cell comprising:
a photoelectric conversion layer; and
a collecting electrode disposed on a surface of the photoelectric conversion layer and extending in a first direction,
the collecting electrode extends in a second direction intersecting the first direction and is connectable to a plurality of wiring members arranged in the first direction, and
the collecting electrode is formed to have a larger thickness at an end in the first direction than at a center in the first direction.

5. A solar cell comprising:
a photoelectric conversion layer; and
a collecting electrode disposed on a surface of the photoelectric conversion layer and extending in a first direction,
the collecting electrode extends in a second direction intersecting the first direction and is connectable to a plurality of wiring members arranged in the first direction, and
the collecting electrode includes an auxiliary electrode at a position at an end in the first direction where the wiring member is scheduled to be disposed.
